(19) United States
(12) Patent Application Publication
(10) Pub. No.: US 2010/0327884 A1
(43) Pub. Date: Dec. 30, 2010

(54) Liquid level and quality sensing apparatus, systems and methods using EMF wave propagation

(76) Inventors: Alan Kenneth McCall, Co. Antrim (GB); Idir Boudaoud, Antibes (FR)

Correspondence Address: Jerry L. Mahurin;The Gates Corporation, IP Law Dept. 10-A3, 1551 Wewatta Street, Denver, CO, 80202, US

(21) Appl. No.: 12/803,331

(22) Filed: Jun. 24, 2010

Related U.S. Application Data
(60) Provisional application No. 61/269,648, filed on Jun. 26, 2009.

(51) Int. Cl. G01R 27/26

(52) U.S. Cl. 324/682

(57) ABSTRACT

A liquid level, composition and contamination sensor generates an RF signal across a resonant circuit that includes a variable inductor and capacitor. The resulting electromagnetic radiation is propagated into the liquid and changes in impedance and resonance of the resonant circuit that result from changes in the conductivity and dielectric properties of the liquid, which are proportional to liquid content and volume, are detected. The conductivity and dielectric properties of the liquid are measured, based on the changed impedance and resonance of the resonant circuit, and are compared to determine aging and contamination of the urea solution by other liquids. Also, an optical sensor may be submerged in the liquid to determine the refractive index of the liquid. The refractive index of the liquid may be used to determine: if the liquid is water or a urea solution; the concentration of a urea solution.

### CROSS-REFERENCE TO RELATED APPLICATION

This application claims the benefit of U.S. Provisional Patent Application Ser. No. 61/269,648, entitled Liquid Level, Composition and Contamination Sensing Apparatus, Systems and Methods Using EMF Wave Propagation, filed Jun. 26, 2009, which is incorporated herein by reference.

### BACKGROUND

1. Field of the Invention

This invention relates generally to systems and methods for sensing the condition of liquid in a tank or container. More particularly, embodiments of the present invention relate to sensing characteristics of automotive urea solution in a urea tank in a motor vehicle, the composition of fuel in a fuel tank, and/or the like, particularly liquid level, composition and contamination, by propagating electromagnetic waves into such a tank.

2. Description of the Prior Art

Selective Catalytic Reduction (SCR) vehicles, also referred to as Euro V vehicles, are diesel powered motor vehicles which are compatible with the use of an operating fluid to reduce emissions. Typically, the SCR vehicle has a urea tank, separate from the fuel tank, which is used to carry an operating fluid such as an automotive urea solution, or the like. Automotive Urea Solution (AUS) is a solution of high purity urea in de-mineralized water. AUS is stored in a urea tank of an SCR vehicle and is sprayed into the exhaust gases of the vehicle in order to convert oxides of nitrogen into elementary nitrogen and water. An SCR vehicle may then advantageously satisfy the Euro V Emissions Standard.

It is important for the Engine Management System (EMS) of an SCR vehicle to have information on the composition of the AUS, so that the EMS may adjust certain vehicle parameters to optimize vehicle performance, specifically emissions control.

In order to ensure this method of reducing emissions in an SCR vehicle remains effective, the quality of the AUS must be maintained. Contaminants, a change in the ratio of high purity urea to other constituents, temperature variation or other changes can impact the life expectancy of the AUS and the effectiveness of the AUS at reducing emissions.

SCR vehicles generally rely on the use of direct measurement systems to determine the level of AUS in a tank. Such systems typically comprise a plurality of sensors disposed at different levels along the vertical plane inside the urea tank. Such sensors typically have poor resolution, are intrusive, and do not detect the quality or temperature of the AUS. Such direct measurement systems also require installation of mechanisms inside the urea tank. Repair, replacement, or adjustment of such an internal direct measurement system is problematic. Furthermore, such systems are ineffective when employed in an SCR vehicle which is exposed to temperatures under minus eleven degrees centigrade, which is the temperature that AUS typically freezes, because such systems do not provide a means of measuring AUS temperature to enable the correct application of heat to prevent freezing of the AUS.

SCR vehicles generally rely on the use of indirect measurement systems to determine the effectiveness of the AUS in reducing vehicle emissions. Such indirect measurements are taken from the exhaust fumes and are passed to the EMS, whereupon the EMS may increase or reduce the quantity of AUS released from the tank. Such systems are typically slow to react and do not accurately reflect the actual quality or composition of the AUS.

Thus, the prior art fails to provide a reliable, inexpensive, and accurate system and method of measuring the level or quality of AUS in a motor vehicle urea tank, let alone both.

Additionally or alternatively, Flex Fuel Vehicles (FFVs) are motor vehicles which are compatible with the use of alcohol as a significant constituent of the vehicle's fuel. Alcohol based fuels are an alternative type of renewable, transportation fuel made from bio-material, potentially reducing dependence on petroleum based fuels. A motorist may advantageously gain increased horsepower for better engine performance because alcohol based fuels typically have a higher octane rating than premium gasoline. Alcohol based fuels include “E85,” a term for motor fuel blends of 85 percent ethanol and 15 percent gasoline. E85 is an alternative fuel as defined by the U.S. Department of Energy and is intended for use in FFVs. Ethanol and other alcohols burn cleaner than gasoline and is a renewable, domestic, environmentally friendly fuel. FFVs can typically be fueled on any blend of ethanol and gasoline, from 0% ethanol and 100% gasoline up to 85% ethanol and 15% gasoline (E85).

It is important for the Engine Management System (EMS) of an FFV to have information on the composition of the fuel, so that the EMS may adjust certain vehicle parameters to optimize vehicle performance, specifically fuel consumption, emissions control and engine power.

Motor vehicle operators generally rely on indirect methods of determining the amount of alcohol in an FFV's fuel tank. The most common method of establishing the alcohol content of the fuel remaining in a motor vehicle is to use software algorithms implemented in the Body Controller Module or EMS of the vehicle. Alcohol content of the fuel may be altered by the driver at each filling of the fuel tank as there is no requirement to continuously use E85 fuel or conventional gasoline. Algorithm-based systems are slow to react to changes in the fuel composition and are typically only accurate to plus or minus ten percent alcohol content. Furthermore, such systems are even more ineffective when employed in a motor vehicle with saddle fuel tanks or similar fuel storage arrangements where the fuel may not be uniformly mixed or where the fuel mixture might change over time as the vehicle is driven.

Direct measurement systems exist, but require installation of a mechanism inside, or in-line with, the fuel line. Repair, replacement, or adjustment of such an internal or in-line fuel composition measurement mechanism is problematic.

The prior art fails to provide a reliable, inexpensive, and accurate system and method of measuring the composition of fuel in a motor vehicle using a system that can be installed external to a fuel line, fuel tank, or the like.

Furthermore, motor vehicle operators rely on fuel gauges to provide accurate information on the amount of fuel remaining in the fuel tank. The most common method of measuring the amount of fuel remaining in a motor vehicle fuel tank is to place a mechanical float and lever inside the tank. When the fuel level changes in the tank, the float causes the lever to pivot. When the lever pivots in response to changing fuel levels, an electrical signal is proportionately generated and/or varied. This variation in electrical signal is transmitted to a fuel gauge or vehicle data bus external to the tank. Such electromechanical fuel measurement systems are not particularly accurate and, of course, require installation of a mechanism inside the tank. Repair, replacement, or adjustment of an internal fuel level measurement mechanism is problematic and the use of such internal level measurements mechanisms may not be practical in urea tanks and/or in flex fuel vehicle fuel tanks due to the relatively more corrosive nature of urea or alcohol.

### SUMMARY

The above problems have been addressed to one degree or another in various patent applications commonly owned with the present application. For example, U.S. patent application Ser. No. 11/431,912, filed May 10, 2006, entitled System and Method for Sensing the Level and Composition of Liquid in a Fuel Tank provides a means to locate a fuel level (and composition) sensor outside of the associated fuel tank. A flex fuel composition sensor, including in-line embodiments, is disclosed in U.S. patent application Ser. No. ______, filed Dec. 18, 2007, entitled Fuel Composition Sensing Systems and Methods Using EMF Wave Propagation. U.S. patent application Ser. No. 11/800,965, filed May 8, 2007, entitled Liquid Level and Composition Sensing Systems and Methods Using EMF Wave Propagation addresses at least some of the aforementioned problems, particularly with respect to sensing the composition and/or level of AUS in an SCR equipped vehicle. Each of the above applications is incorporated herein by reference

The present systems and methods more accurately, and preferably continuously, measure the level, temperature and/or quality (e.g. the composition and/or contamination) of liquid, particularly AUS, in a motor vehicle by means of an internal or external monitoring system. In particular, embodiments of the present invention may be used in SCR vehicles to detect certain characteristics of AUS including the amount of AUS in a urea tank and the percentage of ammonia content, and/or other constituents in the AUS, including contaminates. This information can be reported to the EMS or Body Control Module of the SCR vehicle, allowing the EMS to respond accordingly, thereby allowing adjustments to be made and improve, or at least, maintain the SCR vehicle emissions reduction performance, quickly and accurately. Some embodiments of the present invention detect characteristics of the AUS without any direct contact with AUS, minimizing risk of leaks, or wear of the measuring device due to exposure to ammonia, or the like. To this end, embodiments of the present invention may, be deployed in conjunction with the urea tank at the bottom/side of a urea tank or internal to the urea tank. Some other embodiments may employ direct contact with the liquid, such as through the use of probes to make measurements for use in accordance with the present systems and methods. Various embodiments may provide similar information with respect to fuel in a fuel tank (i.e. alcohol concentration, fuel level, etc.), or similar information with respect to any other fluid in a container.

An object of the present invention, with respect to SCR systems, includes detecting system misuse (water, or other liquids used by customers instead of urea inside the urea solution tank). Another such object is to detecting aging of the AUS, and similarly to measure the concentration of urea solution, which should typically be at 32.5%.

In accordance with embodiments of the present invention, an RF signal is generated across a resonant circuit; which comprises of a variable inductor and capacitor. Electromagnetic radiation is propagated into the liquid to be monitored. As a result, the conductivity and dielectric properties of the liquid change the impedance and resonance of the circuit. These changes, proportional to liquid content and volume, are detected by an on-board microcontroller, or the like, and then transmitted to the main ECU or other engine management electronics.

Embodiments of the present invention determine quality of AUS or other liquid (i.e. composition of the liquid) by measuring and comparing the dielectric and the conductivity of the measured liquid, which respectively represent the real and imaginary part of the complex permittivity at a given optimum frequency. Thereby the present invention is capable of: determining the concentration of urea in AUS; detecting aging of the urea; determining the type of liquid (urea or non-urea) in a tank (for misuse detection); determining the quality (salinity) of water present in a tank; and/or detecting the presence of diesel, oil or any other non-urea based liquids in the AUS.

The permittivity measurement can also be used to detect ice. Ice is detectable in accordance with the present invention in that as a liquid becomes a solid the dielectric and conductivity (permittivity) of the material changes quite considerably during the phase change. Detection of ice in the AUS can also be used to determine the concentration of urea, since a urea solution of 32.5% would freeze at −11° C., and water at 0° C. The concentration of urea in the AUS below 32.5% would raise the freezing temperature by an amount in the eleven degree range between −11° C. and 0° C. directly proportional to the reduced percentage of urea in the AUS. So the combination of sensing a change in physical state of the substance (liquid to solid) and measuring the temperature at which this happens, can be used to determine the urea concentration Also the detection of ice in the urea tank would preferably trigger a heater, which would thaw the ice for the system to function properly and meet legislation demand.

Also, in accordance with the present invention the quality of liquid determination methodology described above can be supplemented by adding an optical sensing element. Optical sensing can be used to help determine more exactly the concentration of urea in AUS.

In accordance with some embodiments, any number, or all measurements of a sensor, such as described above, might be employed to realise a measurement of quality of the liquid, particularly liquid composition and/or contamination. For example a measurement of quality may be compensated with respect to level (volume), and the liquid temperature. This is particularly advantageous in that the complex permittivity (dielectric/conductivity) of liquids, and other materials, change with temperature. Also the circuit parameters measured, which are preferably proportional to complex permittivity (dielectric/conductivity) change as the level of the liquid changes, due to a frequency of operation of the apparatus. However, changing or optimising this frequency can reduce or negate the dependence on the level (volume) of liquid in the tank. In accordance with the present systems and methods another way to reduce or eliminate the effect of the level on quality measures may be to add an electrical ground reference (probe, PCB, plate, cylinder) to the Printed Circuit Board (PCB) of the device, which is in close proximity to the liquid.

The foregoing has outlined rather broadly the features and technical advantages of the present invention in order that the detailed description of the systems and methods that follow may be better understood. Additional features and advantages of the systems and methods will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

The accompanying drawings, which are incorporated in and form part of the specification in which like numerals designate like parts, illustrate embodiments of the present invention and together with the description, serve to explain the principles of the invention. In the drawings:

FIG. 1 is a perspective view of an external embodiment of an AUS system of the present invention deployed in conjunction with a urea tank;

FIG. 2 is a partially fragmented perspective view of an internal embodiment of an AUS system of the present invention deployed in conjunction with a urea tank;

FIG. 3 is a partially fragmented perspective view of an embodiment of an apparatus for liquid level, temperature and quality sensing, in accordance with the present invention;

FIG. 4 is a simplified diagrammatic schematic of an embodiment of the present sensor apparatus and system;

FIG. 5 is a graph showing the permittivity of low conductivity liquids;

FIG. 6 is a graph showing the permittivity of high conductivity liquids;

FIG. 7 is a graph and charts showing the changes in conductivity and dielectric properties of water (left) as salt is added and urea (right) as it is aged, wherein “AB” is an abbreviation for “AdBlue” automotive urea solution, and “NI” is an abbreviation for Northern Ireland;

FIG. 8 is a graph and chart showing the changes in conductivity and dielectric properties of water and urea shown in FIG. 6, and further as water is added to urea;

FIG. 9 is a graph and chart showing the changes in conductivity and dielectric properties of water and urea shown in FIG. 6, with conductivity vs. dielectric data points shown for other liquids shown in the chart;

FIG. 10 is table showing a correlation of capacitance of various liquids with the parallel resistance of these liquids;

FIG. 11 is a graph of the results shown in the table of FIG. 10.

FIGS. 12 and 13 are diagrammatic illustrations of an embodiment of an electro-optic sensor that may be employed in conjunction with the present invention;

FIG. 14 is a graph and charts showing the relative refraction indexes of water, with various salinities, and various urea solutions, as well as an aged urea solution;

FIG. 15 is a graph and chart showing the differences in refractive index in AUS as it is diluted with water (from right to left);

FIG. 16 is a graph and chart showing the relative refraction indexes of various other liquids; and

FIG. 17 is a combination line and bar graph showing the relative refraction indexes of the various other liquids charted in FIG. 16, as well as various concentration of urea solution.

### DETAILED DESCRIPTION

The present systems and methods can determine the type of liquid in a container, particularly where the liquid is substantially water and is not limited to the examples used in this description. In the illustrated and described embodiments, the present system can provide this information to an automotive EMS, which may use the information to prevent improper operation of SCR vehicles with water or the like in the urea tank rather than the AUS recommended by the vehicle manufacturer, as well as to detect the level and or concentration of urea in a tank.

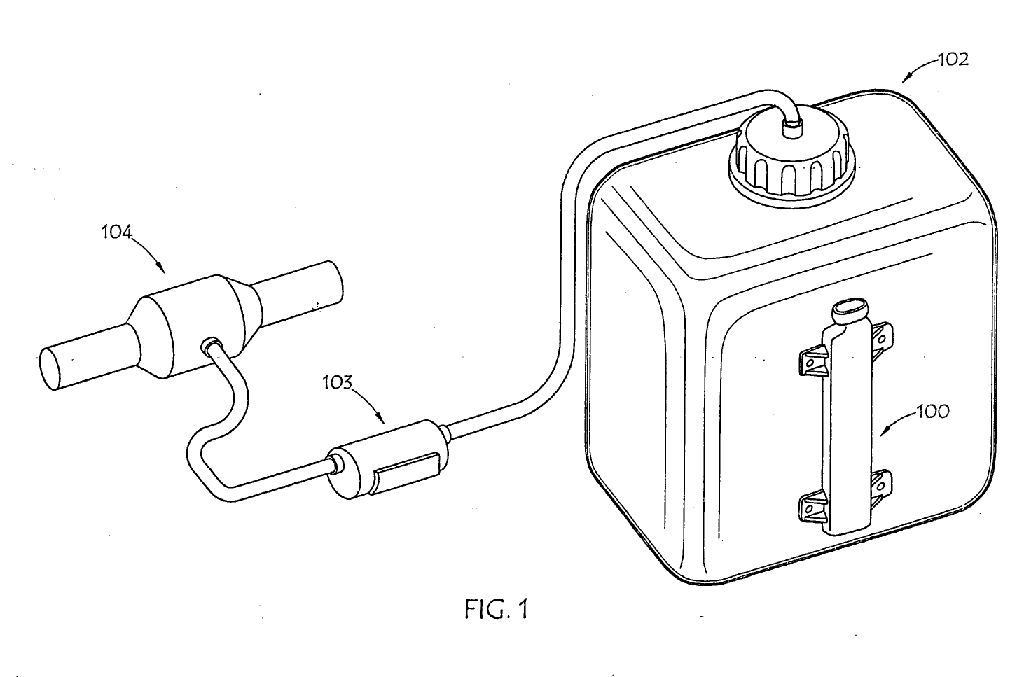

FIG. 1 shows an embodiment of AUS monitoring device 100 of the present invention disposed in conjunction with urea tank 102, such as mounting the AUS monitoring device to the exterior of the tank. Various embodiments call for mounting the AUS monitoring device of the present invention to the exterior side or bottom of a tank. Urea tank 102 may be made from a non-conductive material such as plastic. AUS from urea tank 102 may be pumped by means of a pump 103 into exhaust 104 of a vehicle for emission control purposes.

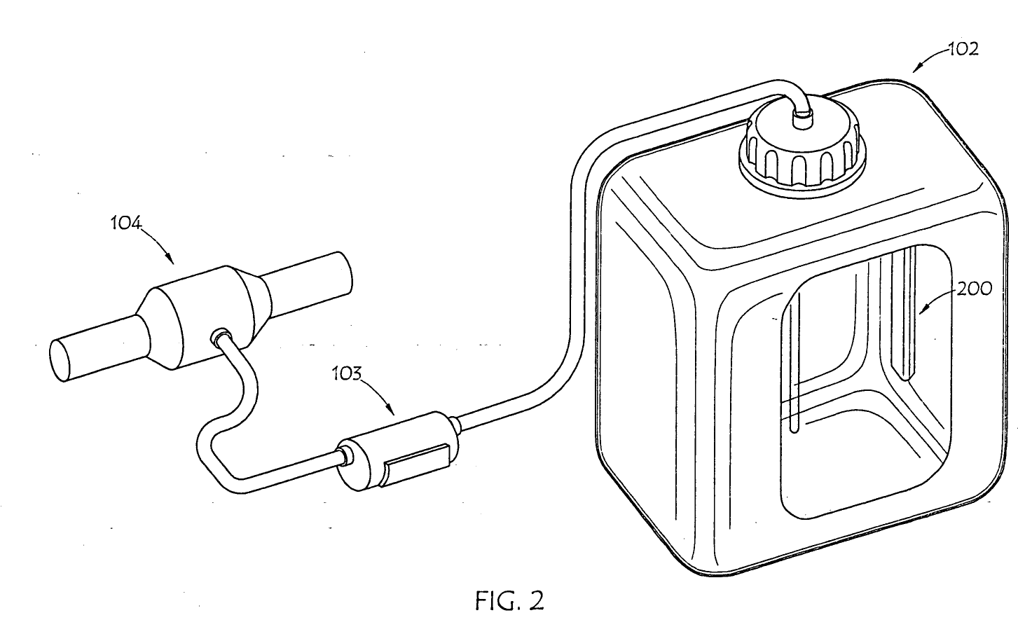

FIG. 2 shows another embodiment (200) of the AUS monitoring device of the present invention disposed in conjunction with urea tank 102, such as mounting the AUS monitoring device 200 to the interior of the tank. This embodiment may be of particular use where urea tank 102 is comprised of a conductive material, such as metal.

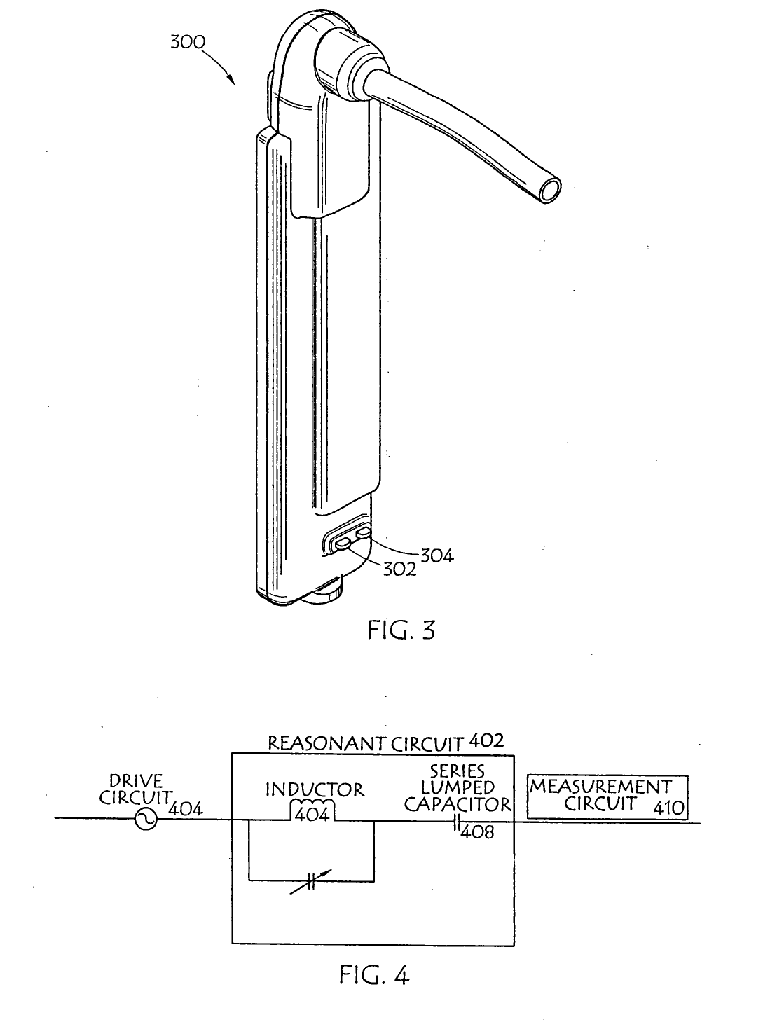

FIG. 3 is a partially fragmented perspective view of an embodiment of sensor 300 for liquid level, temperature and quality sensing, in accordance with the present invention. Sensor 300 is preferably mounted inside a tank such as urea tank 102, shown in FIGS. 1 and 2. Sensor 300 is shown as having probes 302 and 304, which may, for example, be used to make measurements to realize parallel capacitance (Cp) and/or parallel resistance (Rp) for determination of the quality of the liquid, as discussed in greater detail below. Probes 302 and 304 may be used to make such measurements through direct contact with the liquid. Thus in accordance with the present systems and methods may measure liquid properties through direct contact, or without direct contact, with the liquid. Without direct contact has the advantages of minimizing risks of leaks and wear due to exposure to urea solution (ammonia) and the like. However, probes 302 and 304 are preferably made from stainless steel, or the like, to avoid corrosion due to urea exposure.

FIG. 4 is a simplified diagrammatic schematic of an embodiment of the present sensor apparatus and system. An embodiment of such a device (400) might include resonant circuit 402 coupled to drive circuit 404. Resonant circuit 402 preferably includes variable inductor 406 and capacitor 408, with the inductor positioned proximate a liquid in a container. Measurement circuit 410 detects changes in impedance and resonance of the resonant circuit that result from changes in the conductivity and dielectric properties of the liquid, measures the conductivity and dielectric properties of the liquid based on the changed impedance and resonance of the resonant circuit, and may compare the dielectric and the conductivity of the measured liquid.

In accordance with the present invention the resonant frequency (f) of the LCR circuit, such as circuit 402 shown in FIG. 4 is:

$$f = \frac{1}{2 π \sqrt{LC}} \qquad ( 1 )$$

Where C (equivalent capacitance of LCR circuit) is function of the Permittivity of the liquid ∈.

$$C = \frac{ɛ A}{d} \qquad ( 2 )$$

Where A=area of capacitor conductors and d=distance between capacitor conductors.

$${ɛ}^{*} = {ɛ}_{r} + j \frac{σ}{ω} \qquad ( 3 )$$

Where:

∈*=Complex Permittivity or the modulus Permittivity

∈r=Real Permittivity=Dielectric

σ=Imaginary Permittivity=Conductivity

ω=2πf

j=j notation denoting a complex number.

For high conductivity liquids, the frequency shift is proportional to the dielectric of liquid ∈ᵣ and its conductivity σ (per the equations above)

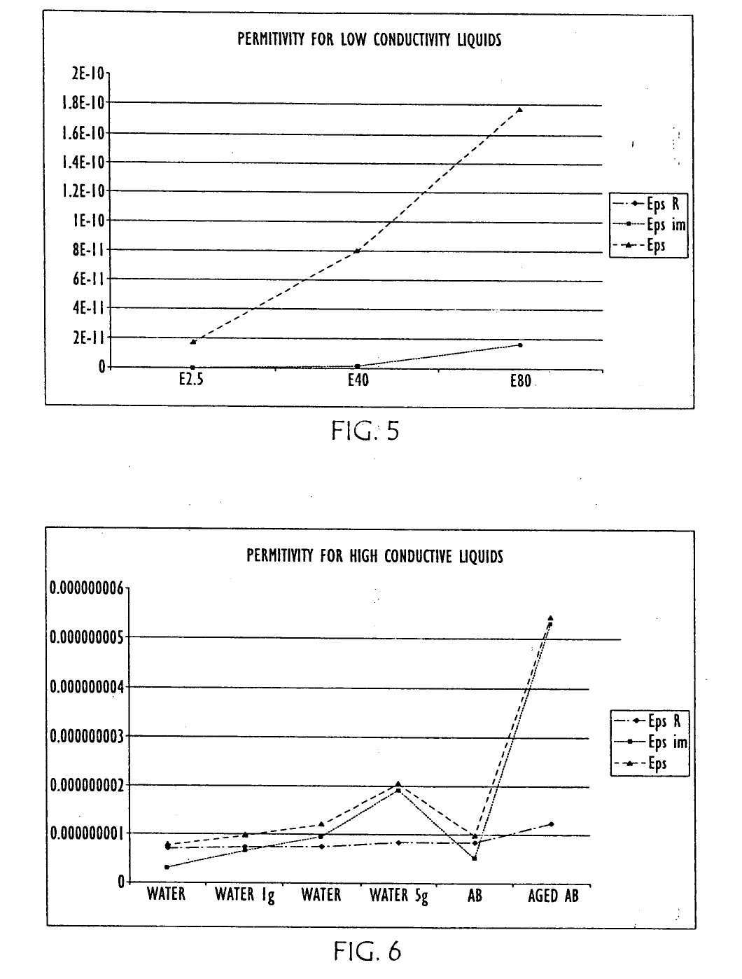

As a result of testing it has been determined that true permittivity of a liquid is more proportional to the real part (dielectric) for low conductivity liquids, but it is more proportional to the imaginary part (conductivity) for high conductive liquids. FIG. 5 empirically shows the former in the illustrated graph of the permittivity of low conductivity liquids, at 10 MHz by way of example, while the graph in FIG. 6 shows the permittivity of high conductivity liquids at 10 MHz. At other frequencies the dielectric and conductivity behave in a different manner. For example, the higher the frequency (i.e. closer to 100 MHz) the true permittivity of a liquid is more proportional to the real part (dielectric) for low and high conductivity liquids. Therefore, in accordance with the present invention, increasing the frequency from 10 MHz allows one to realize the dielectric more readily, as conductivity does not dominate the change in permittivity.

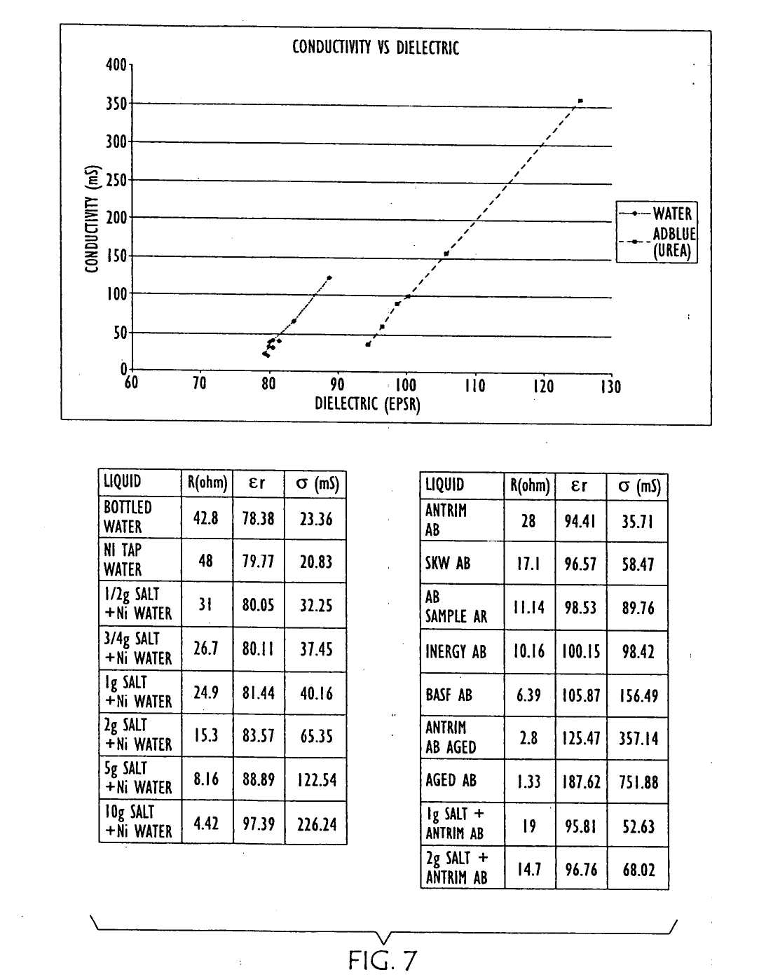

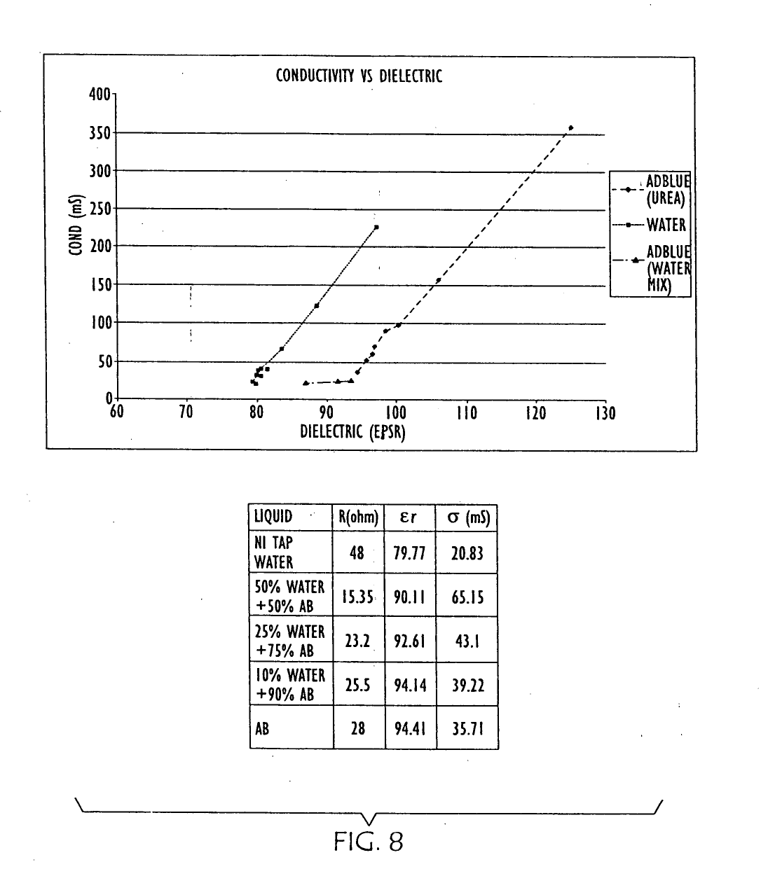

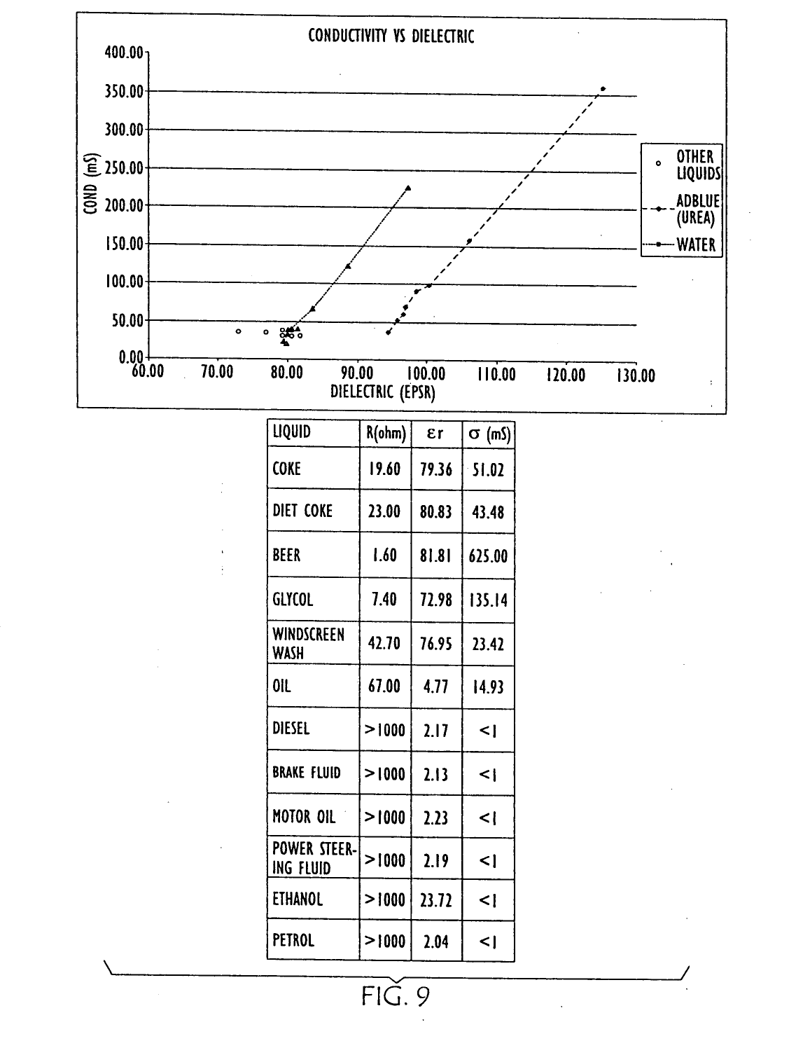

Further empirical data is shown in FIG. 7, where changes in conductivity and dielectric properties of water (left) as salt is added and urea (right) as it is aged are graphed. FIG. 8 is a graph showing further empirical data resulting from dilution of the urea solution. FIG. 9 overlays conductivity and dielectric property data points for other liquids with the data graphed in FIGS. 7 and 8. Thus, to facilitate differentiation between water and urea, both ∈ᵣ and Conductivity are measured in embodiments of the present invention.

Various embodiments of the present methods generate an RF signal across a resonant circuit that includes a variable inductor and capacitor. The resulting electromagnetic radiation is propagated into a liquid to be monitored. Changes in impedance and resonance of the resonant circuit that result from changes in the conductivity and dielectric properties of the liquid are detected. The changes in the conductivity and dielectric properties are proportional to liquid content and volume. The conductivity and dielectric properties of the liquid are measured, based on the changed impedance and resonance of the resonant circuit and the dielectric and the conductivity of the measured liquid are compared.

This comparison might be used to determine the type of liquid in a tank, or the like, such as whether the liquid in the tank is a urea solution or not. If the measured liquid is an aqueous urea solution, the comparison may provide a concentration of urea in the aqueous urea solution and/or detects aging of urea in the aqueous urea solution. Alternatively the comparison might determine a quality of water present in a tank, such quality of water present in the tank may be based on the salinity of the water. Further, where the measured liquid is an aqueous urea solution, the comparison might detect the presence of non-urea-based liquids in the aqueous urea solution, such as diesel fuel, oil, gasoline, or the like.

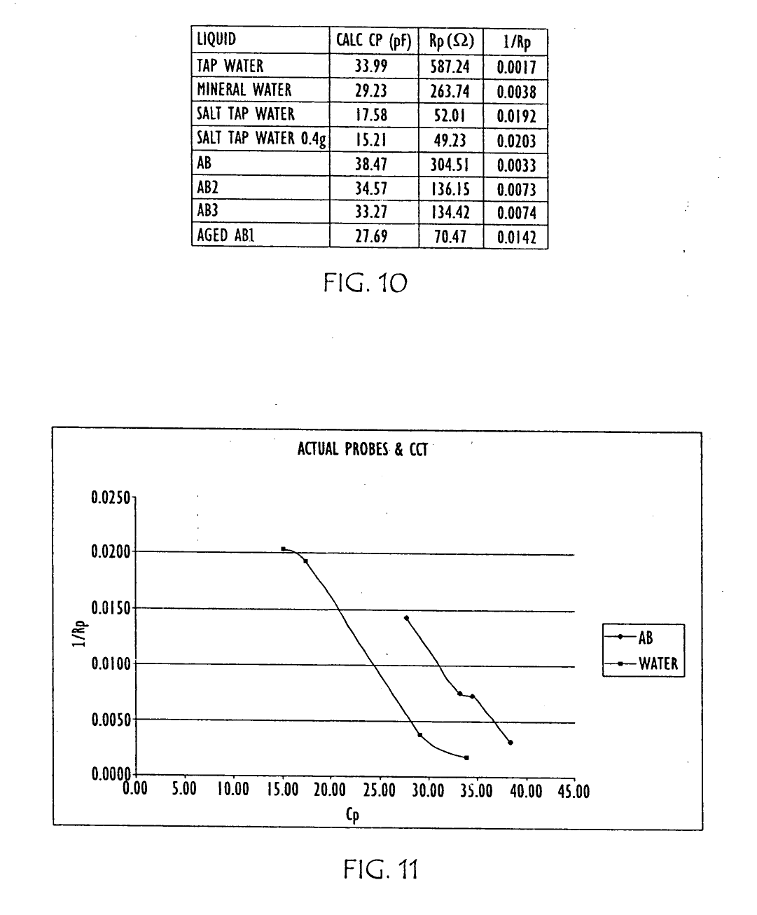

In accordance with further embodiments of the present invention a measure of parallel resistance and parallel capacitance of the liquid may be made. Such parallel resistance and parallel capacitance of the liquid have been found to be proportional to the conductivity and the dielectric of the liquid, respectively. Accordingly, FIG. 10 is a table showing a correlation of capacitance of various liquids with the parallel resistance of these liquids, while FIG. 11 is a graph of the results shown in the table of FIG. 10, highlighting that upon measuring and comparing both conductivity (parallel resistance Rp) and dielectric (Cp) or parameters proportional to each, urea concentration, ageing and contamination can be realized. The measurements shown in FIGS. 10 and 11 may be obtained using an apparatus in accordance with the present invention, such as sensor 300, shown in FIG. 3.

Hence, detection of changes in impedance and resonance of the resonant circuit that result from changes in the conductivity and dielectric properties of the liquid may be derived by measuring parallel resistance and parallel capacitance of the liquid. The parallel resistance of the liquid is proportional to the conductivity of the liquid, while the parallel capacitance of the liquid is proportional to the dielectric of the liquid.

In accordance with some embodiments, any number, or all measurements of a sensor, such as described above, might be employed to realise a measurement of quality of the liquid, particularly liquid composition and/or contamination. For example a measurement of quality may be compensated with respect to level (volume), and the liquid temperature. In particular, the complex permittivity (dielectric/conductivity) of liquids, and other materials, change with temperature. Thus to further refine such measurements made in accordance with the present systems and methods, a temperature of the liquid may be measured and the comparison of the dielectric and the conductivity of the measured liquid may be compensated using the measured temperature of the liquid.

Also, the circuit parameters measured, such as parallel capacitance and parallel resistance, which are proportional to complex permittivity, namely dielectric and conductivity of the liquid, respectively, change as the level of the liquid changes, due to a frequency of operation of the apparatus. Thus, the volume of the liquid deduced from the changes in the conductivity and dielectric properties may be used to compensate the resulting comparison of the dielectric and the conductivity of the measured liquid. Additionally, or alternatively, changing or optimising the frequency of operation of the apparatus can reduce or negate the dependence on the level (volume) of liquid in the tank. In accordance with the present systems and methods another way to reduce or eliminate the effect of the level on quality measures may be to add an electrical ground reference (probe, PCB, plate, cylinder) to a Printed Circuit Board (PCB) mounting circuitry of the device, as the PCB is disposed in close proximity to the liquid.

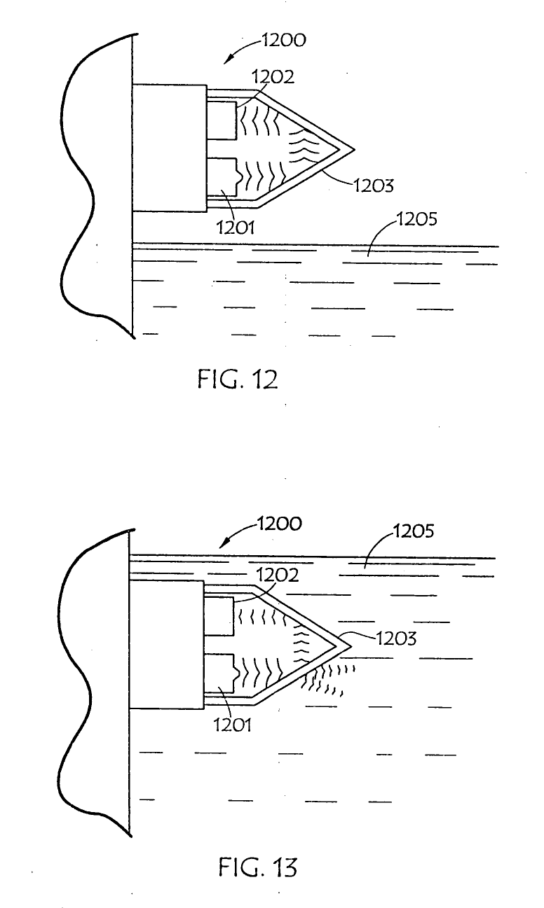

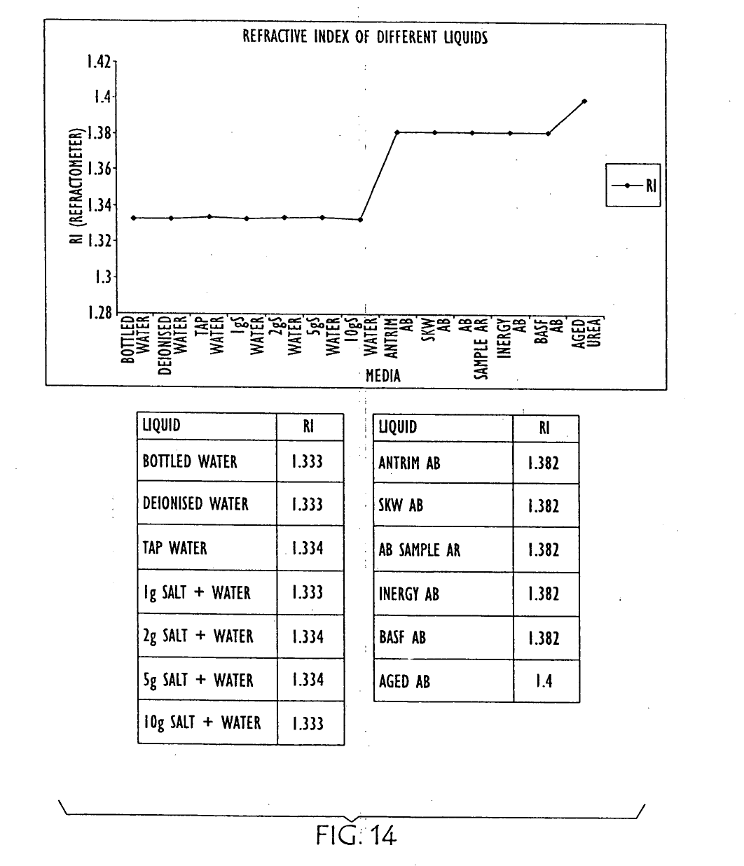

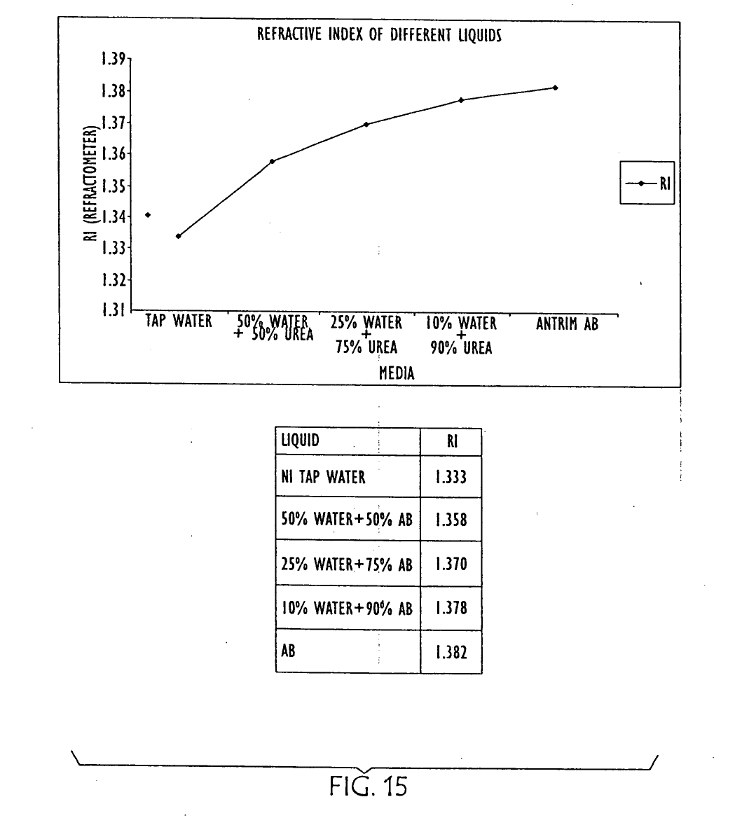

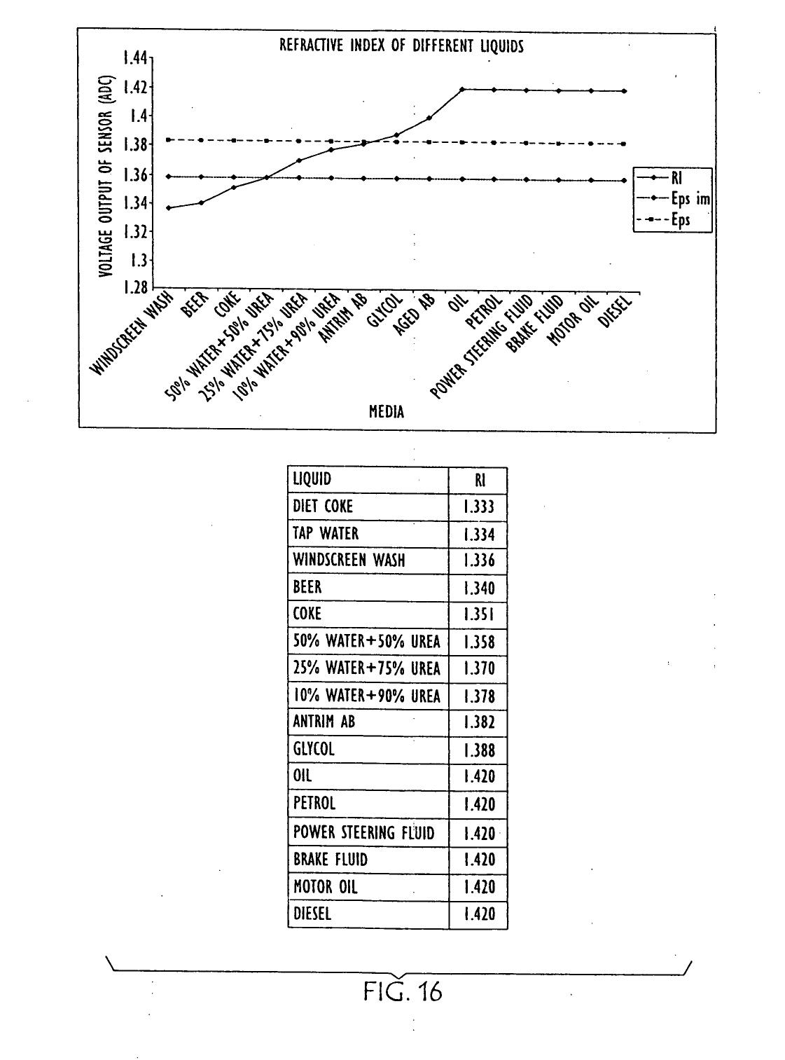

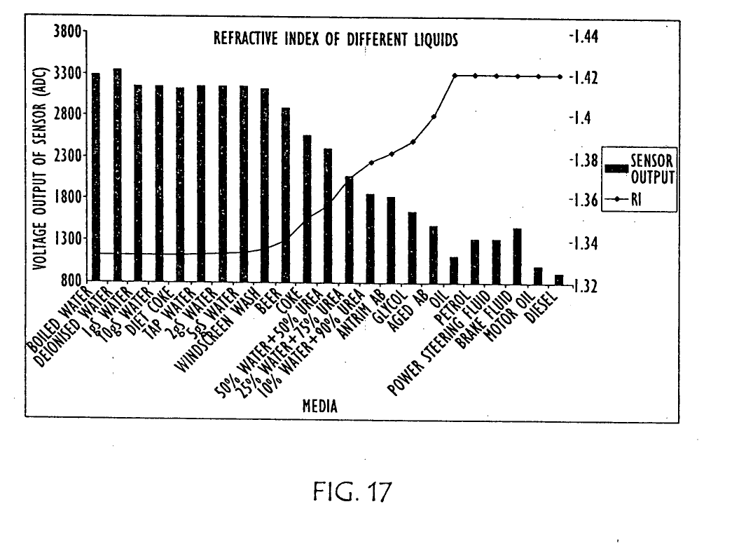

FIGS. 12 and 13 are diagrammatic illustrations of an embodiment of electro-optic sensor 1200 that may be employed in conjunction with the present invention. Electro-optic sensor 1200 contains infrared LED 1201 and light receiver 1202. Light from LED 1201 is directed into prism 1203 which forms the tip of sensor 1200. With no liquid (1205) present (as in FIG. 12) light from the LED is reflected within prism 1203 to receiver 1202. When rising liquid (1205) immerses prism 1203 (as shown in FIG. 13), light is refracted out into the liquid, leaving little light to reach receiver 1202. The light that is received is directly proportional to the refractive index of the liquid. FIG. 14 is a graph and charts showing the relative refraction indexes of water, with various salinities, and various urea solutions, as well as an aged urea solution. FIG. 15 is a graph and table showing the differences in refractive index in AUS as it is diluted with water (from right to left). FIG. 16 is a graph and table showing the relative refraction indexes of various other liquids, and FIG. 17 is a combination line and bar graph showing the relative refraction indexes of the various other liquids charted in FIG. 16, as well as various concentration of urea solution.

Thus, in accordance with various embodiments of the present invention an optical sensor may be submerged in a liquid and light may be directed into a prism forming a tip of the sensor, with the light being refracted out into the liquid. Reflected light received by the sensor is directly proportional to the refractive index of the liquid, which can then be measured to determine whether the liquid is water or a urea solution and the concentration of such a urea solution, based on the refractive index.

The tables and graphs of FIGS. 14-17 show that optical technology is effective to detect the difference between water and urea, whereas the tables and graphs of FIGS. 5-11 show dielectric technology is effective for detecting aging and contamination by other liquids. Thus, use of both technologies in a complementary fashion may be made in accordance with various embodiments of the present systems and methods.

Thus, in accordance with some embodiments of the present invention, a further method might generate an RF signal across a resonant circuit with a variable inductor and capacitor and the resulting electromagnetic radiation may be propagated into a liquid to be monitored. Changes in impedance and resonance of the resonant circuit that result from changes in the conductivity and dielectric properties of the liquid may be detected, wherein the changes in the conductivity and dielectric properties being proportional to liquid content and volume. The conductivity and dielectric properties of the liquid may be measured, based on the changed impedance and resonance of the resonant circuit and the dielectric and the conductivity of the liquid may be compared. Also, in accordance with such embodiments an optical sensor is submerged in the liquid and light is directed into a prism forming a tip of the sensor, such that the light is refracted out into the liquid. Reflected light is received by the sensor, the light received being directly proportional to the refractive index of the liquid, which can then be measured. Thereupon a determination may be made, in accordance with the present embodiments whether the liquid is water or a urea solution and the concentration of such a urea solution, based on the refractive index and aging and contamination of the urea solution by other liquids may be detected based on the comparison of the dielectric and conductivity of the urea solution.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. For example, as noted, the present systems and methods can sense and measure the composition of liquid in other containers and/or transmission lines and are not limited to the examples used in this description. The system can be used in a wide variety of scientific, consumer, industrial, and medical environments. Accordingly, the appended claims are intended to include within their scope such processes, machines, manufacture, compositions of matter, means, methods, or steps.

What is claimed is:

1. A method comprising:
generating an RF signal across a resonant circuit, said resonant circuit comprising a variable inductor and capacitor;
propagating resulting electromagnetic radiation into a liquid to be monitored;
detecting changes in impedance and resonance of the resonant circuit that result from changes in the conductivity and dielectric properties of the liquid, said changes in the conductivity and dielectric properties being proportional to liquid content and volume;
measuring said conductivity and dielectric properties of the liquid based on said changed impedance and resonance of said resonant circuit; and
comparing said dielectric and the conductivity of the measured liquid.

2. The method of claim 1, further comprising measuring a temperature of said liquid.

3. The method of claim 2, further comprising compensating a resulting comparison of said dielectric and the conductivity of the measured liquid using a measured temperature of said liquid.

4. The method of claim 1, further comprising deriving a volume of said liquid using the changes in the conductivity and dielectric properties of the liquid.

5. The method of claim 4, further comprising compensating said resulting comparison of said dielectric and the conductivity of the measured liquid using a resulting measure of the volume of said liquid.

6. The method of claim 1 wherein said detecting changes in impedance and resonance of the resonant circuit that result from changes in the conductivity and dielectric properties of the liquid comprise measuring parallel resistance and parallel capacitance of said liquid.

7. The method of claim 6, wherein said parallel resistance of said liquid is proportional to said conductivity of said liquid.

8. The method of claim 6, wherein said parallel capacitance of said liquid is proportional to said dielectric of said liquid.

9. The method of claim 1, wherein said measured liquid is an aqueous urea solution and said comparing provides a concentration of urea in said aqueous urea solution.

10. The method of claim 1, wherein said measured liquid is an aqueous urea solution and said comparing detects aging of urea in said aqueous urea solution.

11. The method of claim 1, wherein said comparing determines the type of liquid in a tank.

12. The method of claim 11, wherein said comparing determines whether the liquid in said tank is a urea solution or not.

13. The method of claim 12, wherein said comparing determines the quality of water present in a tank.

14. The method of claim 13, wherein said quality of water present in said tank is based on the salinity of said water.

15. The method of claim 1, wherein said measured liquid is an aqueous urea solution and said comparing detects the presence of non-urea-based liquids in said aqueous urea solution.

16. The method of claim 15, wherein said non-urea-based liquid is diesel fuel.

17. The method of claim 15, wherein said non-urea-based liquid is oil.

18. The method of claim 15, wherein said non-urea-based liquid is gasoline.

19. A monitoring device comprising:
a resonant circuit coupled to a driver circuit, said resonant circuit comprising a variable inductor and capacitor said in inductor positioned proximate a liquid in a container; and
means for detecting changes in impedance and resonance of the resonant circuit that result from changes in the conductivity and dielectric properties of the liquid;
means for measuring said conductivity and dielectric properties of the liquid based on said changed impedance and resonance of said resonant circuit; and
means for comparing said dielectric and the conductivity of the measured liquid.

20. The device of claim 19, wherein said liquid is an aqueous urea solution.

21. A method comprising:
submerging an optical sensor in a liquid;
directing light into a prism forming a tip of said sensor, said light being refracted out into the liquid;
receiving reflected light by said sensor, the light received being directly proportional to the refractive index of the liquid;
measuring said refractive index; and
determining whether said liquid is water or a urea solution and the concentration of such a urea solution, based on said refractive index.

22. A method comprising:
generating an RF signal across a resonant circuit, said resonant circuit comprising a variable inductor and capacitor;
propagating resulting electromagnetic radiation into a liquid to be monitored;
detecting changes in impedance and resonance of the resonant circuit that result from changes in the conductivity and dielectric properties of the liquid, said changes in the conductivity and dielectric properties being proportional to liquid content and volume;
measuring said conductivity and dielectric properties of the liquid based on said changed impedance and resonance of said resonant circuit;
comparing said dielectric and the conductivity of said liquid;
submerging an optical sensor in said liquid;
directing light into a prism forming a tip of said sensor, said light being refracted out into the liquid;
receiving reflected light by said sensor, the light received being directly proportional to the refractive index of the liquid;
measuring said refractive index; and
determining whether said liquid is water or a urea solution based on said refractive index and the concentration of such a urea solution, and detecting aging and contamination of said urea solution by other liquids based on the comparison of the dielectric and conductivity of said urea solution.
